(19) United States
(12) Patent Application Publication
(10) Pub. No.: US 2015/0035418 A1
(43) Pub. Date: Feb. 5, 2015

(54) POWER SUPPLY CASE HAVING WATERPROOF STRUCTURE

(71) Applicant: ASIAN POWER DEVICES INC., Taoyuan County (TW)

(72) Inventor: Yung-Sung SHIU, Taoyuan County (TW)

(73) Assignee: ASIAN POWER DEVICES INC., Taoyuan County (TW)

(21) Appl. No.: 14/290,022

(22) Filed: May 29, 2014

(30) Foreign Application Priority Data
Aug. 1, 2013 (TW) 102214532

(51) Int. Cl. H05K 5/06; H05K 5/02

(52) U.S. Cl. CPC H05K 5/069; H05K 5/02
USPC 312/223.1

(57) ABSTRACT

A power supply case having a waterproof structure includes an upper case and a lower case, a waterproof structure is formed by a waterproof groove and a waterproof rib. After the upper case and the lower case are engaged, an engaged status is formed by the waterproof rib and the waterproof groove, and the power supply case is formed with at least an open zone penetrated in the area where the waterproof structure is formed, and characterized in that: a surface of the open zone defined in the waterproof groove is inwardly formed with an extended groove part which is communicated with the waterproof groove. The waterproof structure is able to be matched with a waterproof strip, and the length of the waterproof strip is able to be longer than the length of the waterproof groove.

### BACKGROUND OF THE INVENTION

1. Field of the Invention

The present invention relates to a power supply case having a waterproof structure, especially to a waterproof case structure.

2. Description of Related Art

Power supplies used in various fields are inevitably to be subject to some severe environments such as high temperature or dusty places, for ensuring the safe operation and service life of the power supply, the power supply requires a better sealing and waterproof performance. A conventional power supply case is provided an adhesive member for achieving the required waterproof level; but providing adhesive member has following disadvantages: first, the cost is relatively higher, if a power supply having a greater dimension is desired to be provided with the adhesive member, the required amount of adhesive member is larger and the resource recycling rate is very low; second, the power supply provided with the adhesive member is very difficult to be detached thereby causing the maintenance being hard to be processed; third, after the service life of the power supply has been expired, the disassembly and recycle are not easy to be carried out, so the environment may therefore be damaged.

At present, the interior of a case is additionally provided with a waterproof strip, and the waterproof objective can be achieved by a certain structure being matched and working with the waterproof strip. Please refer to FIG. 1, which is a schematic view showing the prior art. As shown in FIG. 1, a power supply case (1) mainly includes an upper case (10) and a lower case (12), and the upper case (10) and the lower case (12) are respectively provided with a waterproof rib (100) and a waterproof groove (120), and the waterproof groove (120) allows a waterproof strip (14) to be received therein. After the upper case (10) is engaged with the lower case (12), a matched status is formed by the waterproof rib (100) and the waterproof groove (120), and the whole waterproof effect is able to be enhanced through the waterproof strip (14) being disposed between the waterproof rib (100) and the waterproof groove (120).

However, the applicant of the present invention has discovered that during the assembly process of a case, the waterproof strip (14) is mainly made of rubber thereby being provided with an excellent retracting property, so the cutting precision of the waterproof strip (14) is very hard to be controlled, and a situation of the waterproof strip (14) being overly long or overly short may happen. In addition, the assembly is done by a manual force, so during the assembly, the length of the waterproof strip (14) may not be matched with the length of the waterproof groove (120), and an additional process of trimming the waterproof strip (14) is required, which may cause an unnecessary burden to the production line. In a trend of demanding the electronic device to be thinner and smaller, if the waterproof strip (14) is overly long and not trimmed, because the allowable tolerance for all components is limited, the overly-long waterproof strip (14) may exceed the preset tolerance.

### SUMMARY OF THE INVENTION

The present invention is to provide a power supply case having a waterproof structure, wherein with the extension of a waterproof groove of a waterproof structure, the length of a waterproof strip does not required to be as precise as before, thereby allowing the assembly operation to be greatly facilitated.

Accordingly, the present invention provides a power supply case having a waterproof structure. The power supply case includes an upper case and a lower case, a waterproof structure is formed by a waterproof groove and a waterproof rib, and the waterproof groove and the waterproof rib are respectively formed on the upper case and the lower case, wherein after the upper case and the lower case are engaged, an engaged status is formed by the waterproof rib and the waterproof groove, and the power supply case is formed with at least an open zone, the open zone is penetrated in the area where the waterproof structure is formed, and characterized in that: a surface of the open zone defined in the waterproof groove is inwardly formed with an extended groove part, and the extended groove part is communicated with the waterproof groove. Wherein, the waterproof structure is able to be matched with a waterproof strip, and the length of the waterproof strip is able to be longer than the length of the waterproof groove.

Based on what has been disclosed above, when the waterproof strip is assembled in the waterproof groove, with the design of the length of the waterproof strip being able to be slightly longer than the length of the waterproof groove, a part of the waterproof strip would be protruded out of the waterproof groove, and the protruded portion of the waterproof strip is able to be mounted in the extended groove part, thereby facilitating the assembly in factory and lowering the possibility of requiring an additional cutting process.

### BRIEF DESCRIPTION OF DRAWING

FIG. 1 is a schematic view showing the prior art;

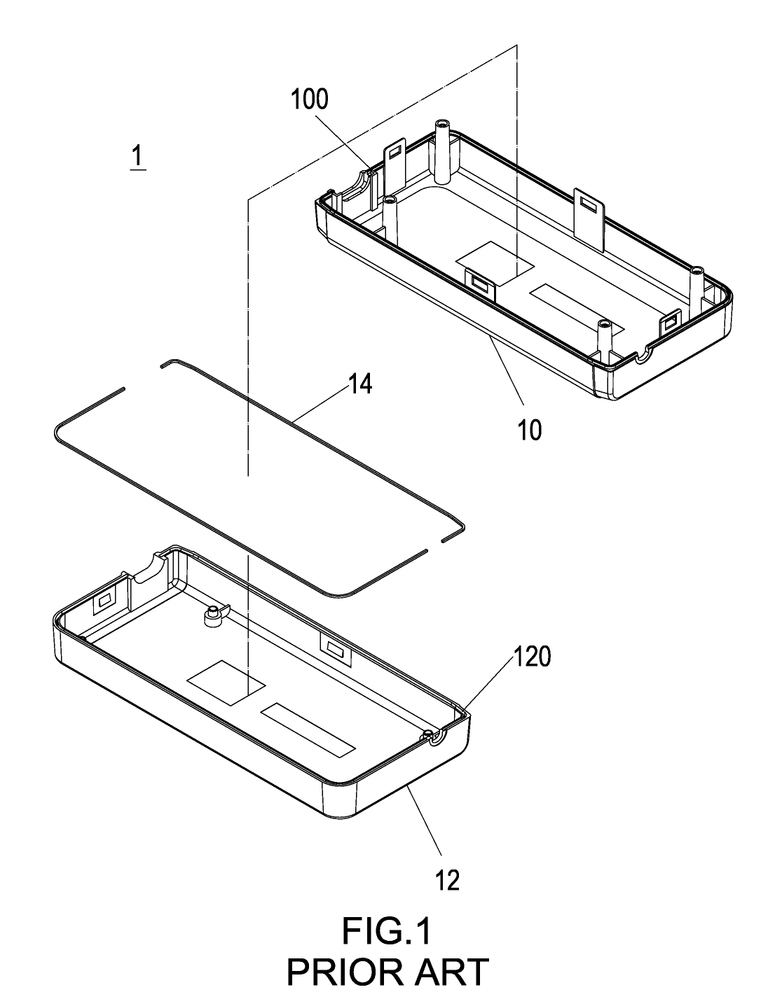

FIG. 2 is a perspective exploded view according to the present invention;

FIG. 3 is another perspective exploded view according to the present invention; and

FIG. 4 is a perspective view showing the assembly according to the present invention.

### DETAILED DESCRIPTION OF THE INVENTION

A preferred embodiment of the present invention will be described with reference to the drawings.

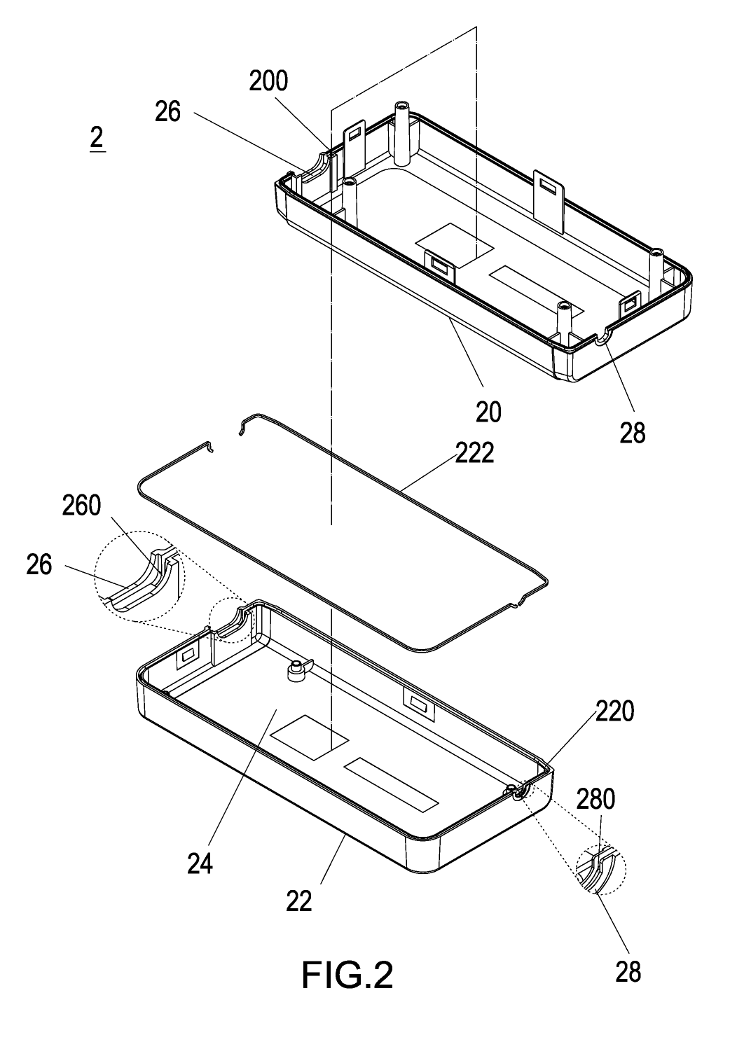

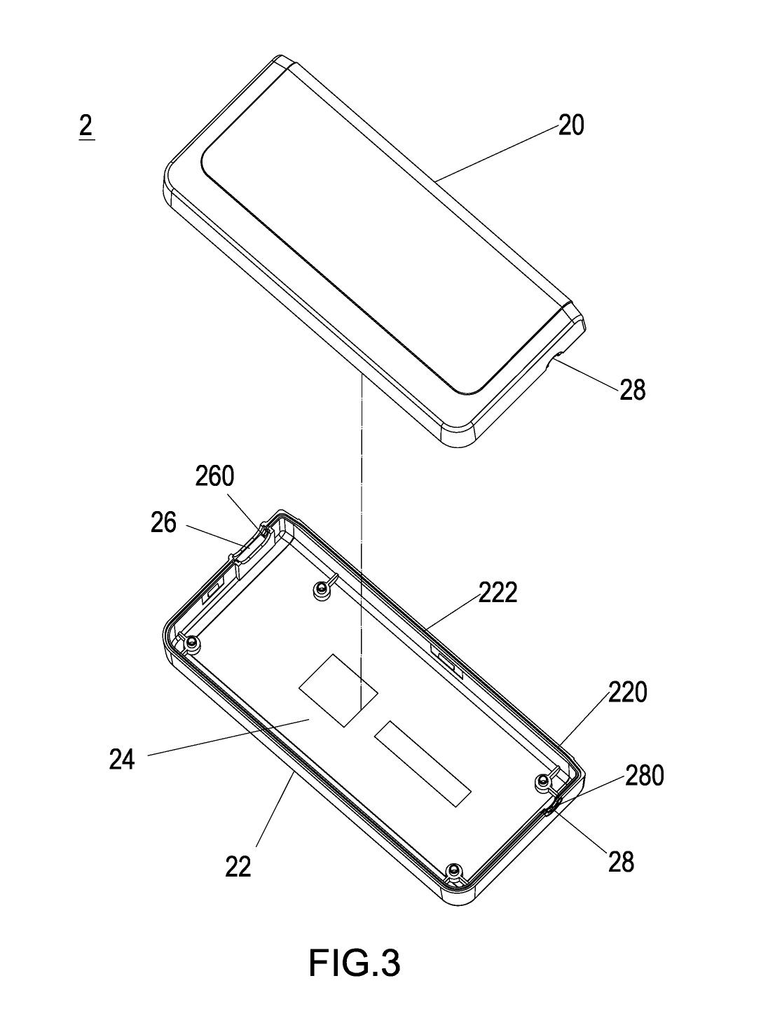

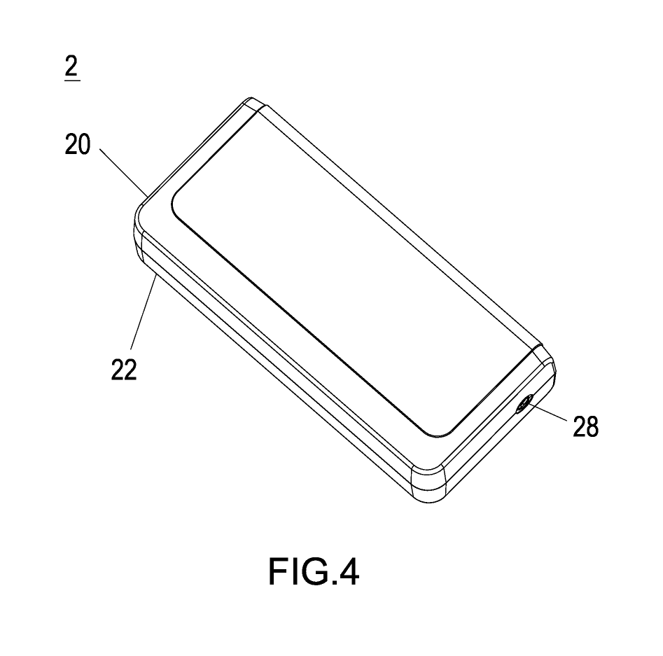

Please refer to FIG. 2 to FIG. 4, wherein FIG. 2 is a perspective exploded view according to the present invention; FIG. 3 is another perspective exploded view according to the present invention; and FIG. 4 is a perspective view showing the assembly according to the present invention. The present invention provides a power supply case (2) which includes an upper case (20) and a lower case (22), wherein a waterproof structure is formed by a waterproof groove (220) and a waterproof rib (200). The power supply case (2) is formed with an accommodation space (24) at the inner side of the waterproof structure and used for accommodating an electronic device (which is not the characteristic of the present invention, therefor not shown in figures), and the waterproof groove (220) and the waterproof rib (200) are respectively formed on the upper case (20) and the lower case (22). According to this embodiment, the waterproof groove (220) is formed on the lower case (22) and the waterproof rib (200) is formed on the upper case (20), however the above-mentioned arrangement is only served for illustration and shall not be a limitation to the scope of the present invention.

The power supply case (2) is formed with at least an open zone, according to this embodiment, two open zones (26, 28) are adopted for illustration, and the open zones (26, 28) are penetrated in the area where the waterproof structure is formed. Wherein, surfaces of the open zones (26, 28) defined in the waterproof groove (220) are respectively and inwardly formed with an extended groove part (260, 280), and the extended groove parts (260, 280) are communicated with the waterproof groove (220).

The waterproof structure is able to work with a waterproof strip (222), the length of the waterproof strip (222) can be longer than the length of the waterproof groove (220), and the material of which the waterproof strip (222) is made can be rubber or plastic. When the power supply case (2) is assembled, the waterproof strip (222) is firstly disposed in the waterproof groove (220); because the length of the waterproof strip (222) is longer than the length of the waterproof groove (220), a part of the waterproof strip (222) is unable to be mounted in the waterproof groove (220) thereby being exposed, and the exposed portion of the waterproof strip (222) is able to be received and mounted in the extended groove parts (260, 280).

After the waterproof strip (222) is disposed, relevant electronic device (not shown in figures) can be accommodated in the accommodation space (24), and the electronic device can be connected to an external cable (not shown in figures), the shape of the cable defined at the end section of the power supply case (2) is matched with the open zones (26, 28) thereby forming a latched status. When the upper case (20) is engaged with the lower case (22), the open zones (26, 28) are provided with a waterproof effect because the cable itself has a waterproof material, and the waterproof groove (220) and the waterproof rib (220) are in contact with each other, so a better waterproof effect is provided through the waterproof strip (222) being disposed between the waterproof groove (220) and the waterproof rib (200).

According to the present invention, instead of limiting the length of the waterproof strip (222) being the same as the length of the waterproof groove (220), the length of the waterproof strip (222) can be between the length of the waterproof groove (220) and a longer length defined by the waterproof groove (220) and the extended groove parts (260, 280), so the allowable cutting range of the waterproof strip (222) is expanded, thereby increasing the cutting efficiency and avoiding a situation of the waterproof strip being overly long during the assembly.

Although the present invention has been described with reference to the foregoing preferred embodiment, it will be understood that the invention is not limited to the details thereof. Various equivalent variations and modifications can still occur to those skilled in this art in view of the teachings of the present invention. Thus, all such variations and equivalent modifications are also embraced within the scope of the invention as defined in the appended claims.

What is claimed is:

1. A power supply case having a waterproof structure, the power supply case including an upper case and a lower case, a waterproof structure being formed by a waterproof groove and a waterproof rib, and the waterproof groove and the waterproof rib being respectively formed on the upper case and the lower case, wherein after the upper case and the lower case are engaged, an engaged status is formed by the waterproof rib and the waterproof groove, and the power supply case is formed with at least an open zone, and the open zone is penetrated in the area where the waterproof structure is formed, and wherein a surface of the open zone defined in the waterproof groove is inwardly formed with an extended groove part, and the extended groove part is communicated with the waterproof groove.

2. The power supply case having the waterproof structure according to claim 1, wherein the waterproof structure is able to be matched with a waterproof strip, and the length of the waterproof strip is able to be longer than the length of the waterproof groove.

3. The power supply case having the waterproof structure according to claim 2, wherein the length of the waterproof strip is shorter than the summed length defined by the length of the waterproof groove and the length of the extended groove part.

4. The power supply case having the waterproof structure according to claim 3, wherein the material of which the waterproof strip is made is rubber or plastic.

5. The power supply case having the waterproof structure according to claim 4, wherein the power supply case is formed with an accommodation space at an inner side of the waterproof structure and used for accommodating an electronic device.
